(19) United States
(12) Patent Application Publication
(10) Pub. No.: US 2007/0181254 A1
(43) Pub. Date: Aug. 9, 2007

(54) Plasma processing apparatus with resonance countermeasure function

(75) Inventors: Tsutomu Iida, Hikari (JP); Ryoji Nishio, Kudamatsu (JP); Yutaka Omoto, Hikari (JP); Masahiro Sumiya, Hikari (JP)

Correspondence Address: MCDERMOTT WILL & EMERY LLP, 600 13TH STREET, N.W., WASHINGTON, DC, 20005-3096, US

(73) Assignee: HITACHI HIGH-TECHNOLOGIES CORPORATION

(21) Appl. No.: 11/362,177

(22) Filed: Feb. 27, 2006

(30) Foreign Application Priority Data
Feb. 3, 2006 (JP) 2006-026485

(51) Int. Cl. C23F 1/00; C23C 16/00

(52) U.S. Cl. 156/345.28; 118/723 E; 156/345.43

(57) ABSTRACT

A plasma processing apparatus has a processing chamber connected to an exhaust system so that the inside pressure can be reduced, a gas feeding unit for supplying gas to the processing chamber, a wafer, and a substrate electrode on which the wafer can be placed. The plasma processing apparatus also has an antenna electrode provided in opposition to the substrate electrode to generate plasma, a plasma generating high-frequency power supply connected to the antenna electrode, and a wafer biasing power supply connected to the substrate electrode. In addition, a coaxial line and a coaxial waveguide are optimized by using a coaxial model, and a voltage measuring circuit is mounted right under the coaxial line.

### BACKGROUND OF THE INVENTION

The present invention generally relates to semiconductor manufacturing technology, and particularly to a plasma processing apparatus with resonance countermeasure function that is suited to process semiconductor wafers by using plasma.

The circuit patterns have become increasingly miniaturized together with the recent highly advanced integration of semiconductor devices. Accordingly, it is necessary to produce the circuit patterns with highly precise dimensions. In addition, the semiconductor wafers have increased their diameters as 300-mm wafers in order to reduce the manufacturing cost of semiconductor devices. In order to increase the yield, wafers are required to uniformly process with high quality by using uniform plasma over a wide range of the wafer from its center to around the outer periphery. When semiconductor products are produced, a high-frequency bias is generally applied in order that fine circuit patterns can be formed with an enough anisotropic pattern formation. At this time, the values of the high-frequency voltage and self-biasing voltage generated on the wafer are the important parameters for the process, and thus it is important to accurately monitor these values.

For this purpose, the high-frequency voltage has so far been detected between the wafer and a matching device of a high-frequency power supply (see, for example, JP-A-2003-174015 and JP-A-2002-203835).

On the other hand, the high-frequency transmission lines affect the high-frequency voltage/current and phase difference. That is, the high-frequency waveform on the output of the high-frequency matching device is different from that on the wafer. Therefore, it is known that the use of a wafer potential probe for directly measuring the wafer potential is effective in order to obtain the potential information of the wafer (see, for examples JP-A-2001-338917).

Moreover, in a conventional plasma generator of parallel plane type having an upper plane electrode made of a metal material and a wafer (operating as a lower electrode), high-frequency biasing voltages of the same frequency are applied to the upper electrode and the lower electrode (wafer). In this case, it is known to use a method for monitoring the voltages and phases at the upper and lower electrodes in order to control the phases of the high-frequency biasing voltages (see, for example, JP-A-8-162292).

### SUMMARY OF THE INVENTION

The troublesome phenomenon interfering with the plasma processing apparatus is the resonance caused by the inductance of a high-frequency feeding system with a stray capacitance or with the electrostatic capacitance of the ion sheath that is formed in front of the electrode of the wafer to make capacitive coupling to the plasma. The resonance caused by the stray capacitance and the inductance of the feeding system occurs independently of that caused by the electrostatic capacitance of the ion sheath and the inductance of the feeding system. In other words, the two resonance phenomena simultaneously occur. Therefore, the voltage information obtained at the measurement point is very different from that actually developed at the wafer or electrode. The question about the prior art is not to essentially consider these resonance phenomena.

The technique disclosed in JP-A-2003-174015 is based on the postulate that the information of voltage or other values obtained at the measurement point is apparently the same as or equivalent to that of the wafer. If this postulate becomes unsatisfied, the accuracy of this technique is significantly reduced.

The invention disclosed in JP-A-2002-203835 focuses attention on the failure of this postulate in the general plasma processing apparatus. This document describes that the voltage/current/phase at the wafer and the impedance of the load viewed from the wafer can be obtained from the information at the measurement point by precisely specifying the equivalent circuits between the wafer and the measurement point of voltage or other values. However, this technique cannot also avoid the influence of the problematic resonance phenomena. This is because the electrostatic capacitance of the ion sheath as a part of a pair of factors of a resonance is not considered in the equivalent circuits of this technique although the other pair of factors of the other resonance, namely the inductance component and the stray capacitance are incorporated in the equivalent circuits. This resonance phenomenon due to the plasma is not predictable in this technique.

In addition, it is very difficult and practically impossible to incorporate the electrostatic capacitance of the ion sheath in the equivalent circuits and accurately evaluate it. This is because the value of the electrostatic capacitance cannot be correctly computed for the following reasons. That is, this electrostatic capacitance is determined by the characteristics (electron density, electron temperature, gas density, and the distribution of these electrons and gases on the wafer) of the plasma that depend upon a large number of parameters such as gas pressure/components and the high-frequency power for generating the plasma, and by the high-frequency biasing power to be applied to the wafer. There is, of course, a theory for computing the electrostatic capacitance, but it is not possible to know the correct values that are to be substituted for the equation of the theory. In other words, the precision cannot be assured.

Moreover, the electrostatic capacitance of the ion sheath is the major factor to determine the load impedance viewed from the wafer. The high-frequency voltage generated at the wafer is determined by the combination of the circuits ranging from the matching circuit to the wafer and of this load impedance. However, the electrostatic capacitance of the ion sheath has the property that it is determined by the high-frequency voltage generated at the wafer. In other words, this electrostatic capacitance and the wafer voltage have a mutual dependence of a nonlinear relation. Therefore, the determination of this electrostatic capacitance and the wafer voltage cannot be solved by the normal equivalent circuit simulation, but it will be settled if the convergence computation by a numerical computation is performed. However, this computation is very difficult to make in real time from the viewpoints of both the collection of the values of the basic data for the start of the computation and the computing time.

Thus, it will be concluded that the technique using equivalent circuits cannot overcome the controversial resonance phenomena. The conclusion is that the technique using equivalent circuits cannot compute the resonance phenomena or cannot assure the precision.

Contrary to the technique of JP-A-2003-174015 or JP-A-2002-203835, the technique of JP-A-2001-338917 directly measures the potential of the wafer, and thus can theoretically avoid the controversial resonance phenomena. This technique, however, has a reliability problem and has a difficulty of the practical application. This technique uses a hard needle made of WC (tungsten carbide) to break through the oxide film and nitride film on the rear side of the wafer and directly measure the wafer voltage. The problem is that the semiconductor manufacturing apparatus for successively processing 0.5 to 1 million wafers cannot assuredly break the films on the rear side of the wafer and stably measure. It is very difficult to design the structure for this operation.

It is well known that the phase is also greatly changed and, in extreme cases, reversed at around the resonance point. In the technique for controlling the phase as in JP-A-8-162292, too, the problematic resonance severely interferes with the control performance. This resonance is caused by the impedance of the high-frequency transmission line and the electrostatic capacitance of the ion sheath. This resonance is also caused not only by the high-frequency biasing voltage applied to the wafer, but also by the high-frequency biasing voltage applied to the electrode opposite to the wafer as described in JP-A-8-162292. The document of JP-A-8-162292 does not consider this resonance about the measurement point of phase, and it implies that the controversial resonance phenomena exert the same critical influence on the measurement as in JP-A-2003-174015, JP-A-2002-203835 and JP-A-2001-338917.

The resonance phenomena found by the inventors of this application will be described in detail. Here, an electrode on which the wafer is placed will be mentioned as an example. However, these two resonance problems similarly occur on any electrode that makes capacitive coupling with the plasma. First, description will be made of the case where a resonance phenomenon appears without plasma when the electrode structure is converted to equivalent circuits and when a voltage measurement (here, the measurement of a peak-to-peak voltage, or Vpp) is made for the equivalent circuits. This resonance is the first one of the two resonance phenomena, or the resonance caused by the stray capacitance and the inductance of the high-frequency transmission line. Then, the resonance phenomenon appearing under the presence of plasma will be described. This phenomenon is the second resonance, or the resonance caused by the electrostatic capacitance of the ion sheath and the inductance of the high-frequency transmission line. For the phase measurement, exactly the same conclusion can also be obtained.

The first resonance, or the resonance caused by the stray capacitance and the inductance of the high-frequency transmission line will be mentioned. FIG. 1 is a block diagram of components ranging from a wafer biasing RF power supply to the electrode. The components are sequentially arranged as the wafer biasing RF power supply, a matching circuit, a Vpp detector, a power supply cable, and the electrode. The components ranging from the RF power supply to the power supply cable are provided in the atmosphere, and the electrode on which the wafer is placed is provided in vacuum. FIG. 2 shows the equivalent circuits of the arrangement shown in FIG. 1. The power supply cable is generally a coaxial line, which has the inductance (L1+L2) and stray capacitance (C1) of the central conductor. The electrode can be divided into a high-frequency transmission line (of which the equivalent circuit is the same as the coaxial structure) and a spray film (C3+R1) for electrostatically absorbing the wafer. To the wafer is connected a voltage-measuring high-voltage probe (8 pF, 10 MΩ) that is not written in the equivalent circuits because of a very high impedance enough to neglect the presence of the probe. The equivalent circuits shown in FIG. 2 are the common representation. The actual electrode has stray capacitances (indicated at Cs1, Cs2), and it is more complicated than that shown in FIG. 2 since it is added with devices such as a focus ring and so on.

FIG. 3A shows the result of having measured the frequency-V1/V2 characteristic of the arrangement shown in FIG. 1 with the actual electrode used. The abscissa is the frequency applied as a bias, and the ordinate is the ratio of voltage V1 to voltage V2. From the result, it will be seen that some resonance points appear at frequencies of 4 MHz and above. Thus, the inductance and electrostatic capacitance of the electrode were measured, and the equivalent circuit was produced and simulated. FIG. 4 shows the result of this simulation. From the above results, it will be understood that the measured resonance phenomena can be reproduced. This can be understood by using the well-known formula of resonance frequency,

$${f}_{0} = \frac{1}{2 π \sqrt{LC}} \qquad ( 1 )$$

In the equivalent circuits shown in FIG. 2, the total inductance Lt of the transmission line was about 1.7 μH and the total stray capacitance Ct of the transmission line and the electrode was about 908 pF. When these values are substituted for the corresponding L and C of the equation (1), the resonance frequency is computed as 4.1 MHz, which is coincident with the measured result. However, only the resonance phenomenon can be reproduced by the simulation, but the voltage ratio is not reproduced. This is because the electric characteristics of the actual structure can hardly be replaced by equivalent circuits that are correct enough to assure the measurement accuracy.

If a resonance occurs at 4 MHz as described above, the reliability of the voltage measured at a lower frequency (2 MHz or above) than this resonance frequency will be reduced depending on the bandwidth (Q-value) of the resonance. It is important that the measured inductance and capacitance of 1.7 μH and 908 pF are not so extremely large. If a high-frequency transmission line of a few millimeters is connected to the electrode, such values of inductance and capacitance are simply produced. According to the inventors' experience, use of a bias of 1 MHz or above will need to consider this resonance phenomenon depending on the design method and apparatus structure.

Then, description will be made of the second resonance, or the resonance due to the electrostatic capacitance of the ion sheath and the inductance of the high-frequency transmission line. Under the presence of plasma, the wafer makes capacitive coupling with the plasma. Therefore, a new electrostatic capacitance due to the plasma is required to consider. In addition, under the presence of plasma the resonant frequency can be considered to further decrease as compared with the cases shown in FIGS. 3A and 4. As to this new electrostatic capacitance, the electrostatic capacitance of the ion sheath formed in front of the wafer is dominant. The thickness dₛₕ of this ion sheath is theoretically given by the following equation,

$${d}_{sh} = 1.36 \frac{\sqrt{2}}{3} {{λ}_{db} ( \frac{2 e {V}_{sh}}{{k}_{B} {T}_{e}} )}^{0.75} \qquad ( 2 )$$

where, λ_{db}: Debye length, e: elementary charge, k_{B}: Boltzman's constant, and Tₑ: electron temperature.

The average voltage Vₛₕ of the sheath can be defined by the following equation,

$${V}_{sh} = \frac{1}{2 π} {\int }_{0}^{2 π} ( {V}_{s} ( τ ) - {V}_{B} ( τ ) ) ⅆ τ \qquad ( 3 )$$

where τ: the angular frequency of bias, Vₛ (τ): the spatial potential of plasma, and V_{B} (τ): the biasing potential.

The final electrostatic capacitance of the ion sheath of thickness dₛₕ is given by

$${C}_{sh} = \frac{{ɛ}_{0} {S}_{W}}{{d}_{sh}} \qquad ( 4 )$$

where ∈₀: the dielectric constant of vacuum, and S_{W}: the area of the wafer.

Since the wafer area is constant in the equation (4), it will be understood that the electrostatic capacitance of the ion sheath is inversely proportional to the thickness of the ion sheath. In other words, the resonant frequency decreases with the decrease of the thickness of the ion sheath. The Debye length is the fundamental length of the electric-field shielding ability of plasma, but decreases in inverse proportion to the plasma density. Since the electron temperature within plasma is changed at most tents of percent and thus can be neglected, it will be seen from the equation (2) that the thickness of the ion sheath decreases with the increase of the plasma density and with the decrease of the biasing voltage. Therefore, it can be concluded that the controversial resonant frequency is not constant, but changes with the change of plasma generation condition and wafer processing condition even in the same apparatus or changes even more if the apparatus are different.

The plasma used for processing semiconductor products has the electron temperature of about 3 eV and the plasma density of 10¹⁰˜10¹² cm⁻³. In addition, the biasing voltage is 100˜4000 Vₚₚ. Thus, the electrostatic capacitance of the ion sheath becomes about 200˜8000 pF. The resonance was simulated by using the above values. FIG. 5 is a schematic diagram of the equivalent circuits resulting from the simulation. This diagram corresponds to the addition of plasma's load to the equivalent circuits shown in FIG. 2. When values of C5=2000 pF and R3=160Ω of a typical plasma circuit (corresponding to 300-mm wafer) were given in the equivalent circuits, the result shown in FIG. 6 was obtained. From the result, it was understood that the resonant frequency was reduced to 3 MHz. From FIG. 5, it will be seen that the capacitance C5 is connected in series with C3, or the electrostatic capacitance of the spray film. The resultant electrostatic capacitance of C3 and C5 causes a resonance in corporation with the inductance (L1˜L4) of the transmission lines. Here, if C3=7500 pF (corresponding to 300-mm wafer) is assumed, the resultant capacitance is 1579 pF. If this value and 1.7 μH are substituted for the equation (1), the resonant frequency is 3.1 MHz, which coincides with the result of the simulation. This implies that the resonant frequency under the presence of plasma is determined by the resultant electrostatic capacitance of the ion sheath and the spray film, and by the inductance of the transmission lines. Since the electrostatic capacitance of the spray film takes a value unique to the apparatus, it can be concluded that the resonance phenomenon itself is caused by the inductance of the transmission lines and the electrostatic capacitance of the ion sheath.

This was demonstrated in the actual apparatus. FIG. 7 shows the frequency-V1/V2 characteristic curve with the wafer biasing power supply operated to supply a constant voltage of 20 V as Vpp on the electrode. From the curve, it will be seen that the resonant frequency is extremely reduced to 2 MHz as theoretically predicted above. The resultant electrostatic capacitance can be estimated to be about 4300 pF by using 1.7 μH for the inductance. In this case, since Vpp is very low, the electrostatic capacitance of the sheath reaches about 10000 pF. Thus, it will be understood that the resonant frequency is greatly reduced as predicted when the biasing voltage is low.

As illustrated in FIG. 5, the electrostatic capacitance of the electrode (correspond to that of the spray film on the lower electrode because it is dominant) is connected in series with that of the ion sheath. The effect of the electrostatic capacitance connected in series will be examined. If the electrostatic capacitance of the ion sheath, the electrostatic capacitance of the spray film and the resultant electrostatic capacitance are respectively represented by Csh, Cel and Ctot, the resultant capacitance Ctot that is a serial resultant is calculated from the following equation,

$$Ctot = \frac{Csh \times Cel}{Csh + Cel} \qquad ( 5 )$$

FIG. 8 shows the result of calculating the effect of Cel on this Ctot. In FIG. 8, Csh is a value depending upon the process condition, but Cel is determined by the design. The Ctot that determines the resonant frequency could be controlled by controlling this Cel. From the equation (5), it will be understood that the maximum of Ctot equals to Csh when the Cel is infinite and that a condition of Ctot<Csh is satisfied when the Cel is finite. In other words, the effect of the Cel is to reduce the Ctot, and hence to increase the resonant frequency. This suggests that the resonant frequency can be increased by inserting a small electrostatic capacitance in series with Csh and Cel.

In order to examine this effect, simulation was made by using C3=100 pF in the equivalent circuits shown in FIG. 5. FIG. 9 shows the result of this simulation. From FIG. 9, it will be seen that the resonant frequency due to the electrostatic capacitance of the ion sheath is increased to 22 MHz. However, another resonance appears at about 6 MHz. This resonance is due to the inductance L1˜L4 (1.7 μH) and stray capacitance C1, C2 (350 pF). In other words, as described above, the resonance due to the stray capacitance and the inductance of the high-frequency transmission lines is independent of the resonance due to the electrostatic capacitance of the ion sheath and the inductance of the high-frequency transmission lines. These two resonant frequencies are required to increase. In addition, these inductance and stray capacitance can be traced back to the power supply cable and the high-frequency transmission line of the electrode's inside shown in FIG. 5, and thus these always exist from the structure point of view. Therefore, apparent reduction of the electrostatic capacitance of the ion sheath will be effective only when the resonant frequency of the high-frequency transmission lines is much higher than the actually used frequency.

However, the result shown in FIG. 9 has a fatal defect. This drawback is that the V1/V2 ratio is as extremely low as substantially 0.1. This is because the impedance of C3 is increased due to C3=100 pF with the result that the voltage drop across the capacitance C3 becomes large enough that it cannot be neglected. In addition, since this voltage drop is changed with the impedance of the plasma (including the electrostatic capacitance of the sheath), the measurement accuracy is hard to assure. If this voltage drop is eventually tried to neglect, a capacitor of 10000 pF or above needs to be connected. In this case, the effect of increasing the resonant frequency is adversely almost lost.

As described above, the way to insert a capacitor in series seems somewhat effective, but has a demerit. The circuit elements common to the resonance due to the ion sheath and the resonance due to the high-frequency transmission lines mentioned so far are the inductance of the high-frequency transmission lines. Thus, all the resonant frequencies can be expected to increase by decreasing this inductance.

In order to examine this, simulation was made by decreasing the inductance of all the high-frequency transmission lines to ¼ as much as in FIG. 5. Theoretically, the resonant frequency will be increased twice by using the equation (1). FIG. 10 shows the result of the simulation. From the result, it will be seen that the resonant frequency is twice as high as in FIG. 6, or 6.3 MHz as predicted. In addition, there is not resonance at frequencies below this 6.3 MHz. In other words, the two controversial resonant frequencies can be increased at a time by decreasing the inductance of the high-frequency transmission lines as the circuit element common to each resonance.

The conclusion and problems obtained as above will be summarized as follows. First, there are two controversial resonance phenomena. The first one is caused by the inductance and stray capacitance of the high-frequency transmission lines. The second one is caused by the inductance of the high-frequency transmission lines and the electrostatic capacitance of the ion sheath. Thus, the resonance phenomena themselves based on this principle are never extinguished. In addition, when an electrostatic capacitance is connected in series with the inductance of the transmission line as in the electrode on which the wafer is placed, this electrostatic capacitance also strongly governs the resonant frequency. The resonant frequency derived from the electrostatic capacitance of the ion sheath is heavily dependent on the biasing voltage and plasma density, and thus greatly changed with the change of the wafer processing condition. Since this resonant frequency is associated with the electrostatic capacitance of the spray film, the range of resonant frequencies is unique to the apparatus.

The smaller these inductance and electrostatic capacitance are, naturally the higher the resonant frequency becomes according to the equation (1), thus it being advantageous. When the high-frequency bias lies around this resonant frequency, the voltage value measured at the measurement point is much different from the actual voltage produced on the wafer. In addition, the ratio of the voltage at the measurement point and the wafer voltage depends on the wafer processing condition and thus it is not constant. It is practically impossible to quantitatively compute the voltage produced on the wafer by using the equivalent circuits. The measurement of the phase and current is also impossible.

The sizes of the wafer and liquid crystal substrate to be treated by the semiconductor processing apparatus have so far been increased for the reduction of the manufacturing cost. This trend can be predicted to continue although it depends on the technology. Thus, the increase of the size, or area of the substrate such as wafer will increase the electrostatic capacitance of the heath, and hence reduce the resonant frequency as is apparent from the equation (4). Therefore, the technique proposed according to the invention is essential for the high frequency application in the future semiconductor manufacture.

Accordingly, it is an objective of the invention to provide a technique capable of easily setting the voltage and phase measurement to any target precision even under the presence of the above resonance phenomena.

The main feature of the invention for achieving the above objective is to arrange so that the transmission lines (coaxial lines) provided between the upper electrode or lower electrode and the voltage-or phase-detector has such inductance (L) and electrostatic capacitance (C) as to generate resonant frequencies with no influence on the actual analysis/measurement.

In addition, the voltage-or phase-detector is provided separately from a matching device, and directly connected in series with the coaxial line that is connected to the upper or lower electrode.

Other objects, features and advantages of the invention will become apparent from the following description of the embodiments of the invention taken in conjunction with the accompanying drawings.

### BRIEF DESCRIPTION OF THE DRAWINGS

FIG. 1 is a block diagram of an arrangement of components ranging from the wafer biasing RF power supply to the electrode.

FIG. 2 is a diagram showing the equivalent circuits of the arrangement shown in FIG. 1.

FIG. 3A is a graph showing the frequency characteristic curve of the arrangement shown in FIG. 1.

FIG. 3B is a graph showing the frequency/resonant-frequency characteristic curve of the arrangement shown in FIG. 1.

FIG. 4 is a graph showing the result of simulation by using the equivalent circuits shown in FIG. 2.

FIG. 5 is a diagram of the equivalent circuits of an arrangement of components ranging from the wafer biasing RF power supply to the plasma.

FIG. 6 is a graph showing the result of the simulation by using the equivalent circuits shown in FIG. 5.

FIG. 7 is a graph showing the frequency characteristic curve with Vpp of 20 V kept constant on the electrode.

FIG. 8 is a graph showing curves computed about the effect of Cel on Ctot.

FIG. 9 is a graph showing the result of simulation by using the equivalent circuits shown in FIG. 5.

FIG. 10 is a graph showing the result of simulation with the inductance of high-frequency transmission lines being reduced to ¼.

FIG. 11 is a diagram showing the structure of the coaxial cable.

FIG. 12 is a graph showing the dependence of the outer conductor diameter c on the resonant frequency.

FIG. 13 is a graph showing the dependence of the inner conductor radius a on the resonant frequency.

FIG. 14 is a diagram showing the detector in position.

FIG. 15 is a diagram showing the matching device that has a built-in detector and that is directly connected to the electrode.

FIG. 16 is a diagram showing the detector built in the electrode.

FIG. 17 is a graph showing the dependence of the coaxial tube length L on the resonant frequency.

FIG. 18 is a graph showing the dependence of the inner conductor radius a on the resonant frequency.

FIG. 19 is a graph showing the optimum solution of Reso_Line and Reso_sh.

FIG. 20 is a graph showing the dependence of the electrostatic capacitance Csh of the sheath on the resonant frequency.

FIG. 21 is a graph showing the result of simulation with the electrostatic capacitance Csh of the sheath selected as 2000 pF.

FIG. 22 is a graph showing the result of simulation with the electrostatic capacitance Csh of the sheath selected as 10000 pF.

FIG. 23 is a schematic diagram of a plasma matching apparatus according to the first embodiment.

FIG. 24 is a schematic diagram of a plasma matching apparatus according to the optimization of the first embodiment.

FIG. 25 is a graph showing the comparison between the directly measured wafer voltage and the voltage detector output.

FIG. 26 is a schematic diagram of the plasma matching apparatus of the second embodiment.

FIG. 27 is a schematic diagram of the plasma matching apparatus according to the optimization of the second embodiment.

FIG. 28 is a graph showing the measured phase difference between the frequency generated on the wafer and the phase measurement circuit.

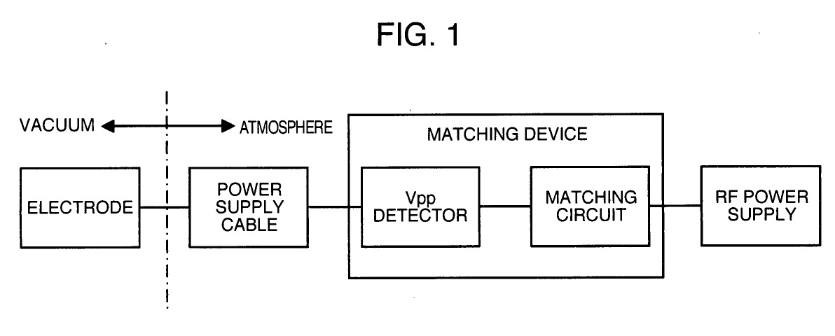

### DETAILED DESCRIPTION OF THE EMBODIMENTS

The resonance cannot be eliminated and it cannot be corrected by computation or calibration as described above. Thus, only the method to solve this problem is to construct the apparatus so that the voltage or phase information at the measurement point can be made equivalent to or equal to that at the electrode (the electrode such as the wafer that makes capacitive coupling with the plasma) to be measured. This apparatus structure needs to raise the resonant frequency not to affect the voltage detection.

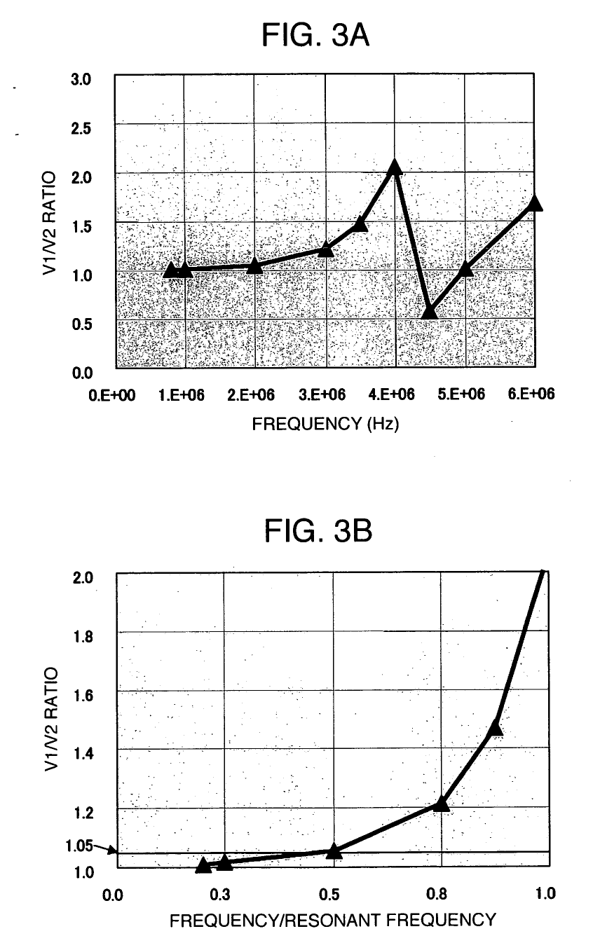

First, the resonant frequency is made as high as possible. Here, the term “the lowest resonant frequency” is represented by a symbol fL. The lowest resonant frequency is defined as the lowest resonant frequency appearing in certain plasma processing apparatus and under a range of the working conditions of this apparatus. Now, the resonant frequency of 4 MHz shown in FIG. 3A is selected and used to indicate the ratio of frequency/4 MHz on the abscissa as shown in FIG. 3B. Then, we consider the case of targeting the apparatus of which the voltage measurement precision is, for example, ±5%. From 3B, it will be seen that the condition that meets the voltage measurement precision of ±5% (V1/V2 is in the range from 0.95 to 1.05) is below the frequency ratio of 0.5. Therefore, it will be understood that the apparatus needs to be constructed so that this lowest resonant frequency can be increased at least twice or more as high as the biasing high frequency (represented by fB) to be used. Thus, the influence of the resonance phenomenon on the measurement of voltage or phase can be reduced to a negligible level or below. This relation can be expressed as
fL>2fB (6)
When the equation (1) is substituted for the equation (6), and rearranged, the condition for the inductance and electrostatic capacitance that generate a resonance can be derived as
LC<(4πfB)⁻² (6′)
where L is the typical value of the inductance such as the inductance of transmission lines, and C is a typical value of the electrostatic capacitance associated with the resonance, that is, the stray capacitance of the high-frequency transmission lines or the electrostatic capacitance of the ion sheath (including the electrostatic capacitance in series with the electrostatic capacitance of the ion sheath).

As described above, the resonant frequency is determined by the electrostatic capacitance of the ion sheath, the inductance of the high-frequency transmission lines and the electrostatic capacitance and stray capacitance connected in series with this inductance. The electrostatic capacitance of the ion sheath depends on the apparatus and the working conditions of this apparatus, and thus it is generally an uncontrollable parameter. In addition, the electrostatic capacitance of the spray film of the electrode is determined by the dielectric constant and thickness of the spray film material. If the wafer to be used is 300 mm in diameter, the capacitance of the spray film is about 2000˜50000 pF. However, the electrostatic capacitance of the spray film does not become a freely controllable parameter from the standpoints of wafer-absorption and-destaticization systems, the performance of those systems and the withstand voltage. The same is also true for the stray capacitance.

The electrostatic capacitance of the spray film is desired to be as large as possible in order that the voltage drop across its impedance can be neglected. The electrostatic capacitance of the spray film has no effect of reducing the resonant frequency since it is inserted in series with the high-frequency transmission line. Therefore, it is desired rather to keep this capacitance not changed for avoiding any demerit than to decrease it so that the resonant frequency is raised to incur another demerit. In addition, it is desired to suppress the stray capacitance between the electrode and the ground to the minimum so that the resonant frequency due to the transmission line can be increased.

As described above, in order to avoid the effect of the resonance, it is necessary that the voltage or phase information at the measurement point be equivalent or equal to that at the electrode (the electrode such as the wafer that makes capacitive coupling with plasma) to be measured. In other words, it is vital that the resonant frequency is required to rise only between the measurement point and the electrode being measured. Another problem is posed by the presence or absence of the resonance in all the high-frequency transmission lines laid over the path from the high-frequency power supply through the matching device to the electrode, but it is meaningless as far as this technique is concerned.

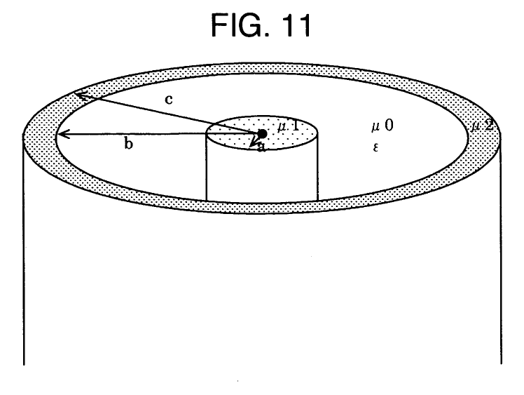

Thus, the first countermeasure against the problems is to reduce the inductance between the measurement point (the Vpp-detector or phase-detector) and the electrode being measured to the extent that meets the equation (6). When the inductance is reduced to ¼ as much as in the result shown in FIG. 6, the result shown in FIG. 10 can be obtained. Thus, this method will be found effective. In order to reduce the inductance, two ways can be considered. One of the ways is to reduce the inductance of the actual high-frequency transmission line. This approach includes the way to simply shorten the high-frequency transmission line and the way to change the high-frequency transmission line itself to a low-inductance structure. The other one is to bring the measurement point close to the electrode being measured. This is equivalent to the shortening of the high-frequency transmission line. Although these two techniques can be separately employed, they may be combined to more increase the resonant frequency.

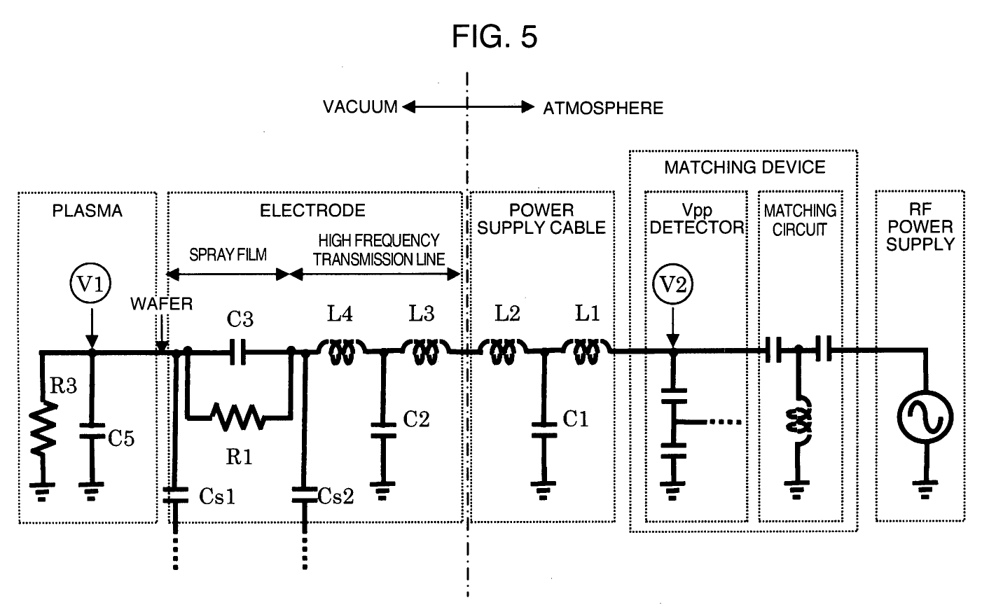

Now, we consider shortening the high-frequency transmission line. For example, the power supply cable and the high-frequency transmission line within the electrode in FIG. 5 are shortened to ½ the original length, thereby enabling the resonant frequency to increase to about 1.4 times as much. However, the shortening of the power supply cable greatly affects the layout of the matching device when the semiconductor manufacturing apparatus is used. In addition, the shortening of the high-frequency transmission line within the electrode affects the function of the electrode (for example, it narrows the up-and-down operating range of the electrode if the electrode has the function to operate up and down). Therefore, the shortening of the high-frequency transmission line has a limit. If the resonant frequency is not raised enough by this method, another technique for increasing the resonant frequency is also necessary to use as described above.

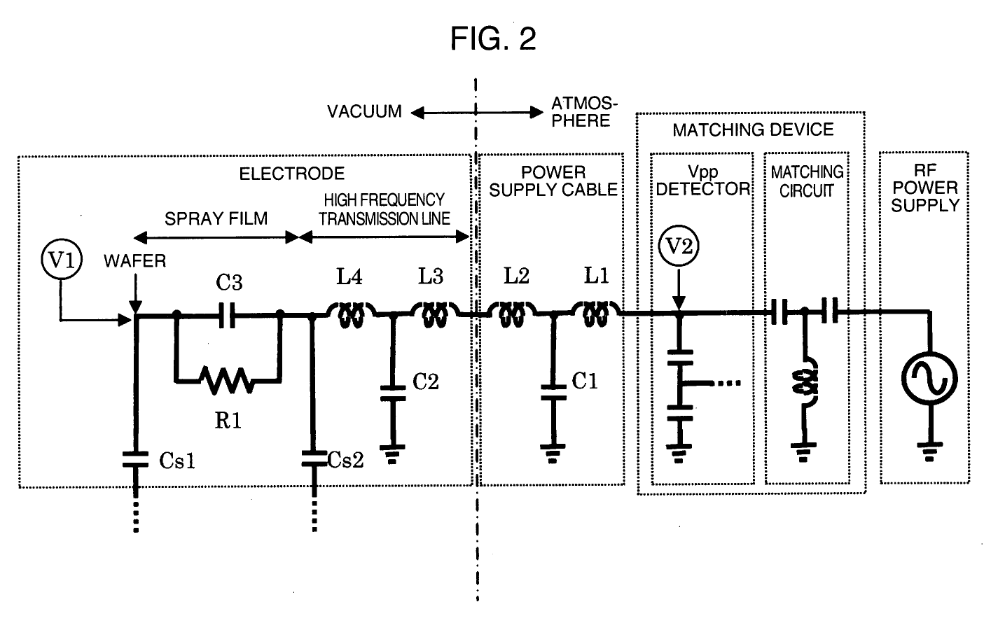

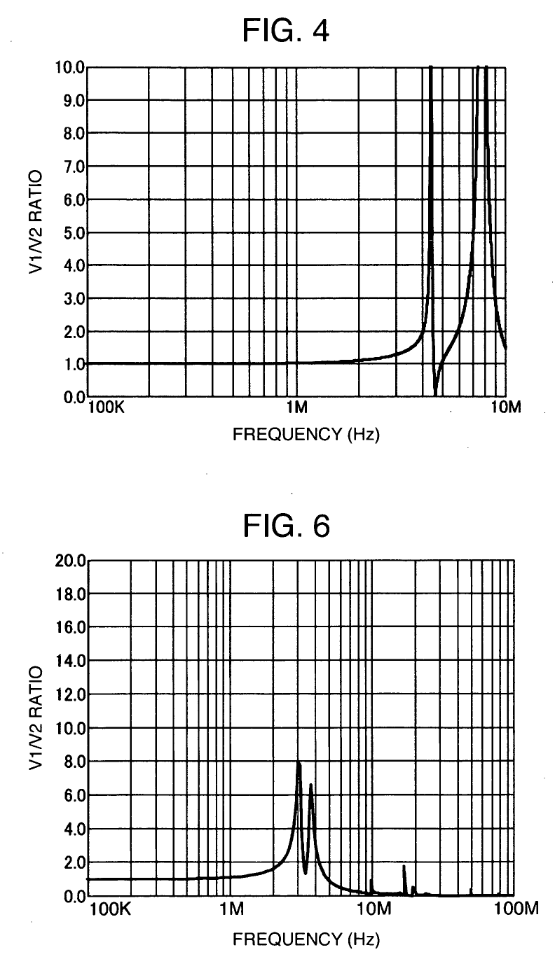

Description will be made of a specific method based on the above description to increase the resonant frequency. Here, a simple resonance model for reproducing the results of FIGS. 4 and 6 is produced for the optimum theoretical solution. For this purpose, the power supply cable and the high-frequency transmission line within the electrode shown in FIGS. 2 and 5 are represented by a single high-frequency transmission line.

The high-frequency transmission line needs to have a structure for shielding the periphery of the central conductor in order to carry high power. The most common structure is the coaxial structure shown in FIG. 11. High-frequency power flows in the inner conductor (of radius a and relative permeability μ1) surrounded by the grounded outer conductor (of inner diameter b, outer diameter c and relative permeability u2). In this case, a condition of a<b<c is satisfied. A high-frequency return current flows in this outer conductor. Therefore, the currents flowing in the inner conductor and outer conductor are of the same value but in the opposite directions. The space between the inner conduct and the outer conductor is filled with a dielectric substance of relative permeability μ0 and specific dielectric constant ∈ (that may be gas, liquid or solid or replaced by vacuum).

If the length of the coaxial structure shown in FIG. 11 is represented by l, the inductance (Induct) of the coaxial structure can be given by

$$Induct = \frac{l}{4 π} [ \frac{μ 1}{2} + 2 μ 0 ln ( \frac{b}{a} ) + \frac{μ 2}{{c}^{2} - {b}^{2}} ( \frac{2 {c}^{4}}{{c}^{2} - {b}^{2}} ln ( \frac{c}{b} ) - \frac{3 {c}^{2} - {b}^{2}}{2} ) ] \qquad ( 7 )$$

The important conclusion can be derived from this equation (7). In other words, in order to minimize the inductance, it is necessary that all the relative magnetic permeability factors (μ0, μ1, μ2) be 1. That is, the inner conductor and outer conductor must be made of nonmagnetic materials, or electric conductive materials. The dielectric substance needs to be nonmagnetic material.

The electrostatic capacitance (Cap) between the inner conductor and the outer conductor will be estimated. This capacitance can be calculated from the following equation.

$$Cap = \frac{2 π ɛ 1}{ln ( \frac{b}{a} )} \qquad ( 8 )$$

The important conclusion can also be derived from this equation (8). In other words, the specific dielectric constant in the intermediate space of the coaxial structure needs to be as small as possible. If possible, it is desired to use a specific dielectric constant of 1 (namely, vacuum layer or gas layer). If a liquid or solid material is filled in the space to increase the withstand voltage, the desired material is quartz of a specific dielectric constant of 3 rather than aluminum oxide of a specific dielectric constant of 9. In addition, the material that is more preferable is gas or solid fluorocarbon of a specific dielectric constant of about 2.5. Of course, a hybrid structure containing vacuum or gas layer may be employed that is effective to further lower the dielectric constant. As one of this hybrid structure, the outer surface of the inner conductor and the inner surface of the outer conductor are coated with a Teflon coating thick enough to assure the withstand voltage, and vacuum (or gas) layer is provided between the outer conductor and the inner conductor.

It is assumed that the matching device of the high-frequency power supply is connected to one end of the coaxial structure shown in FIG. 11 and that the voltage or phase detector is provided at the output end of the matching device. In addition, it is assumed that the electrode that makes capacitive coupling with the plasma is connected to the opposite end of the coaxial structure. This electrode is usually a large-area flat plate. Thus, it is assumed that this electrode has no inductance component. However, such electrode is often surrounded by a grounded conductor because of its structure, and thus it is necessary to estimate the stray capacitance Cs between this electrode and the grounded conductor. If the electrode and the grounded conductor constitute a simple structure, the stray capacitance can be simply calculated. If the structure is complicated, the stray capacitance can be measured or computed by using a commercially available electromagnetic field simulation soft. Here, the method for calculating this stray capacitance Cs will not be described.

Thus, the resonant frequency (Reso_Line) due to the inductance and stray capacitance of the high-frequency transmission line can be calculated from the following equation (9) that is derived by rewriting the equation (1).

$$Reso\_Line = \frac{1}{2 π \sqrt{( Cap + Cs )} \times Induct} \qquad ( 9 )$$

where if l=3.3 m, a=2 mm, b=18.5 mm, c=22 mm, Cs=700 pF, and ∈=2.5, then Induct=1.7 μH, and Cap=206 pF. Thus, Reso_Line=4.1 MHz. That is, the results shown in FIGS. 3A and 4 can be reproduced.

In addition, if the electrostatic capacitance of the ion sheath and the electrostatic capacitance of the electrode head are selected as Csh=2000 pF and Cel=7500 pF, respectively, the resonant frequency (Reso_sh) due to the electrostatic capacitance of the ion sheath can be calculated as Reso_sh=3.1 MHz from the equation (5) and the following equation (10). Thus, the result shown in FIG. 6 can be reproduced.

$$Reso\_sh = \frac{1}{2 π \sqrt{Ctot \times Induct}} \qquad ( 10 )$$

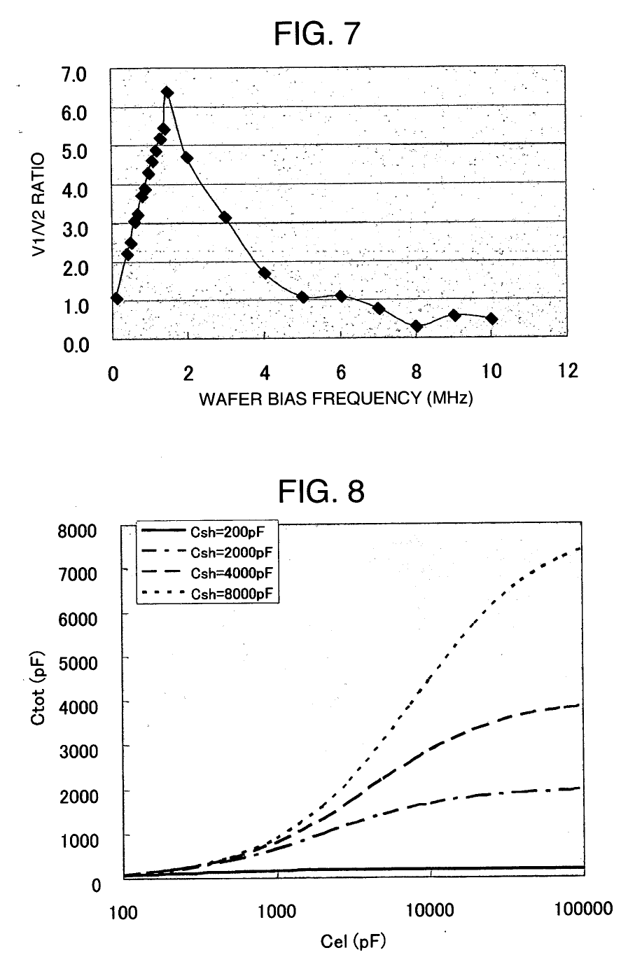

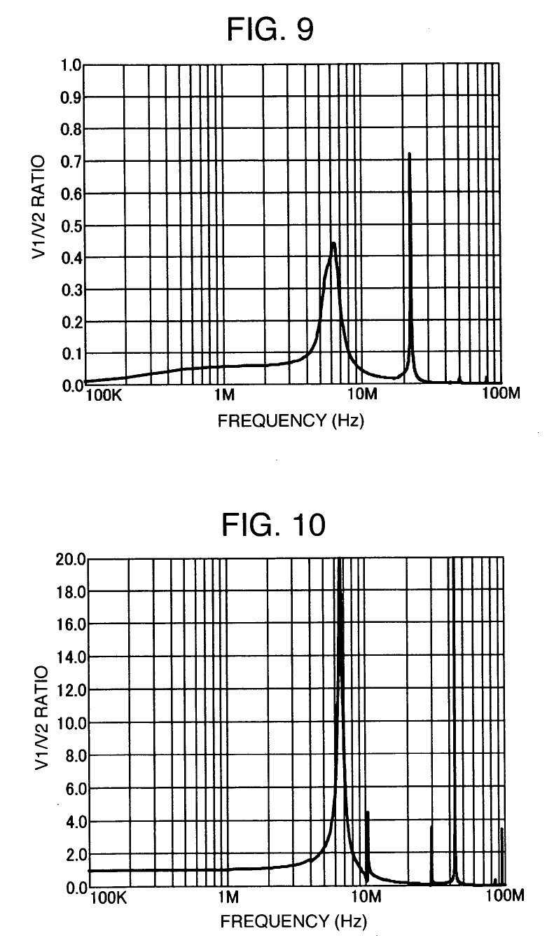

As described above, it will be understood that the experimental results shown in FIGS. 3A and 7 can be analyzed not only by the equivalent circuit simulation but also by the theoretical equations (9) and (10). Thus, description will be made of the way to estimate the optimum shape by using the shape parameters a, c and l of the coaxial tube.

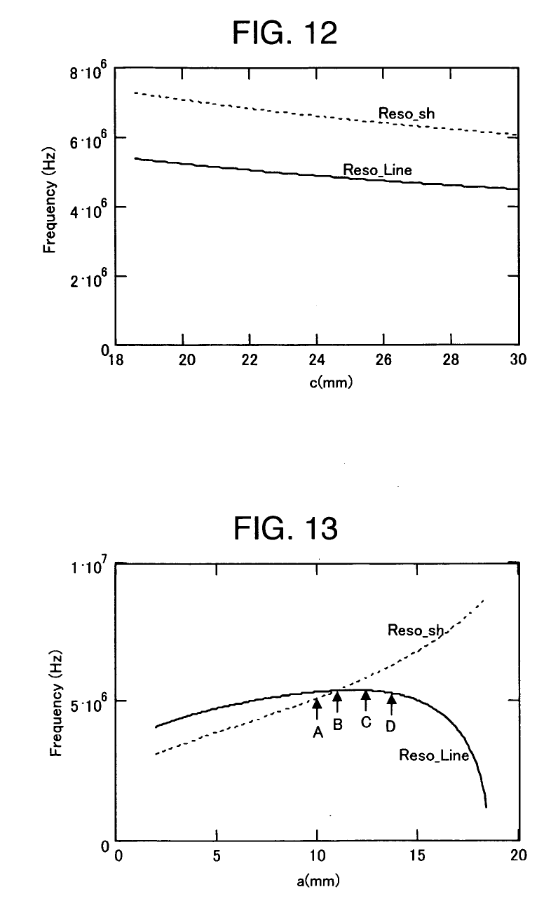

First, the c-dependence will be examined by using a=15 mm, b=18.5 mm and l=3.3 mm. FIG. 12 shows the result. From FIG. 12, it will be seen that the resonant frequency simply decreases with the increase of c. This is because the return current flows in the outer conductor in opposition to the current flowing in the central conductor. In other words, although the leakage fluxes due to the respective currents cancel out each other so that the leakage flux of the whole coaxial structure, or the inductance can be determined, the leakage fluxes less cancel out each other when c is larger than a, so that the inductance increases. Therefore, it will be concluded that the outer conductor should be as thin as possible as long as the design allows.

Then, the a-dependence will be examined when b=18.5 mm, c=22 mm and l=3.3 mm. FIG. 13 shows the result. From the equation (7), it will be obvious that the inductance of the coaxial structure monotonously decreases with the increase of the radius a of the inner conductor. Therefore, the resonant frequency (Reso_sh) due to the electrostatic capacitance of the ion sheath as given by the equation (10) monotonously increases. However, the electrostatic capacitance of the coaxial structure given by the equation (8) increases with the increase of radius a. The resonant frequency (Reso_Line) due to the inductance and stray capacitance of the high-frequency transmission line as given by the equation (9) is determined by the product of the decreasing Induct and the increasing Cap. If a increases, the rate of increase of Cap exceeds the rate of decrease of Induct, and thus the resonant frequency Reso_Line has the maximum value. Here, the lowest resonant frequency fL of equation (6) can be defined by the following equation.
fL=min(Reso_Line,Reso_{—}sh) (11)
where the notation of min(x, y) is the mathematical expression that means the “smaller one of x and y.” The optimum solution in FIG. 13 is the radius a that makes the fL the maximum. FIG. 13 shows an example of the a-dependence. If the dependence on b, c and l is also considered, the optimum structure of FIG. 11 can be said to be the combination of a, b and c that makes the equation (11) the maximum when the length l has a finite value.

Here, the optimum solution of FIG. 13 will be derived. The four points of A, B, C and D in FIG. 13 will be examined. The point B is at a point of (a=10.975 mm) and corresponds to the intersection of the curves of Reso_Line and Reso_sh. Point A is at a smaller position of radius a than point B, and this position of point A is assumed as a=10.0 mm. Point C is the position corresponding to the maximum value of the curve Reso_Line, or which gives largest a within the error (a=11.9 mm). Point D is at a larger position of radius a than point C, and this position of point D is assumed as a=13.0 mm. The lowest resonant frequencies fL for these four points are calculated as follows.

For point A, fL: fL=min (5.348 MHz, 5.118 MHz)=5.118 MHz,

For point B, fL: fL=min (5.395 MHz, 5.395 MHz)=5.395 MHz,

For point C, fL: fL=min (5.408 MHz, 5.677 MHz)=5.408 MHz, and

For point D, fL: fL=min (5.368 MHz, 6.043 MHz)=5.368 MHz.

Thus, the point C in the figure is the optimum solution, or a=11.9 mm, and fL=5.408 MHz.

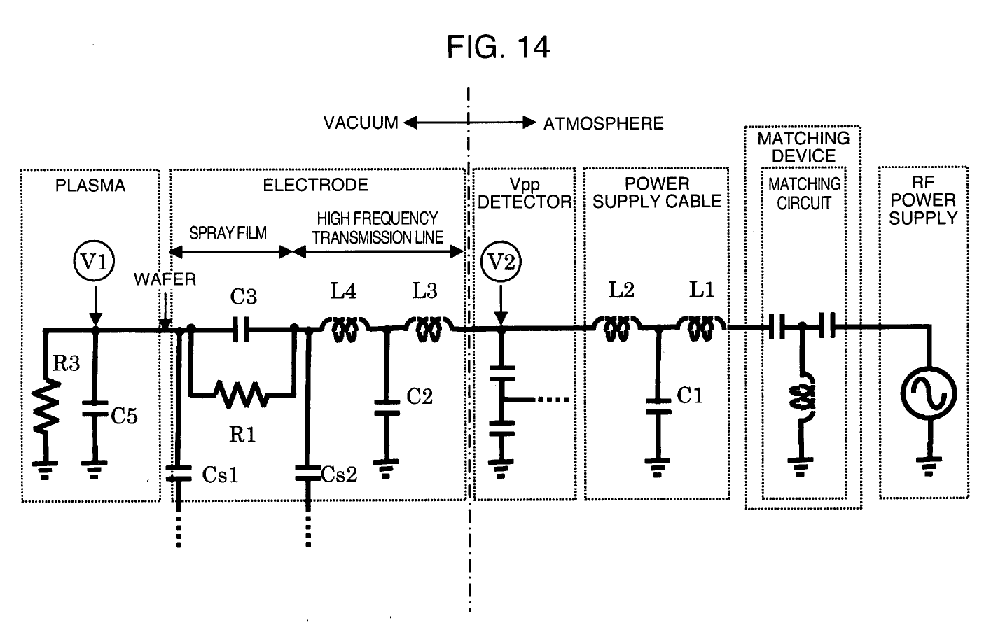

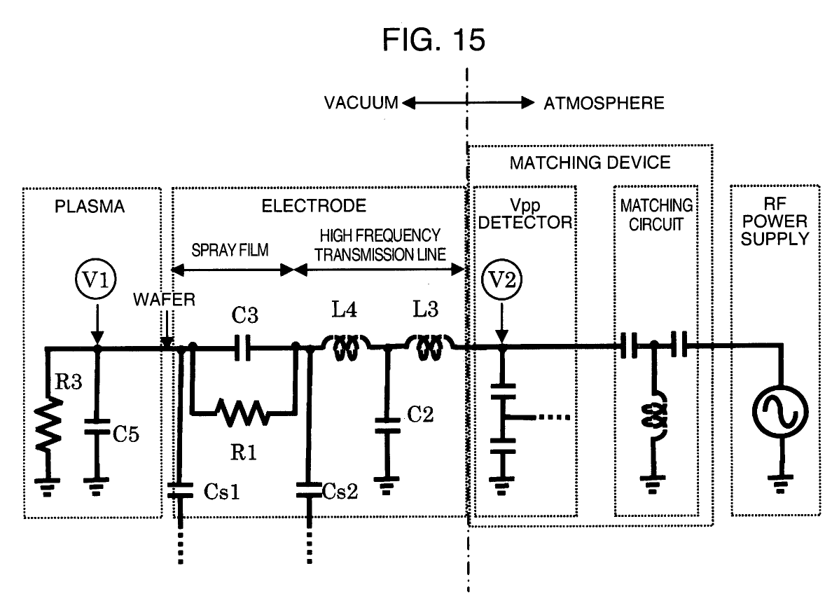

Even if the lengths of the high-frequency transmission lines are shortened, it is difficult to expect a satisfactory effect because of the difficulty in the layout and function of the apparatus as described previously. Since the voltage-or phase-detector is associated with the control system of the high-frequency power supply, it is generally built in the matching device. However, if this detector is separated from the matching device and provided at an appropriate position, the same effect as in the shortening of the high-frequency transmission lines can be obtained. FIG. 14 is a block diagram showing the equivalent circuits for this purpose. From the comparison of FIG. 14 with FIG. 5, it will be seen that the detector is provided between the electrode and the power supply cable in FIG. 14. The merit of this arrangement is that the L1, L2 and C1 of the power supply cable are not necessary to consider for the resonance. In addition, this approach is equivalent to the direct connection of the matching device having a built-in detector to the electrode in terms of the function as shown in FIG. 15. When the matching device is directly connected to the electrode, however, the matching device must be relatively small, and have a space left under the electrode in order to be mounted thereon. Therefore, the arrangement shown in FIG. 15 cannot be used as a common method.

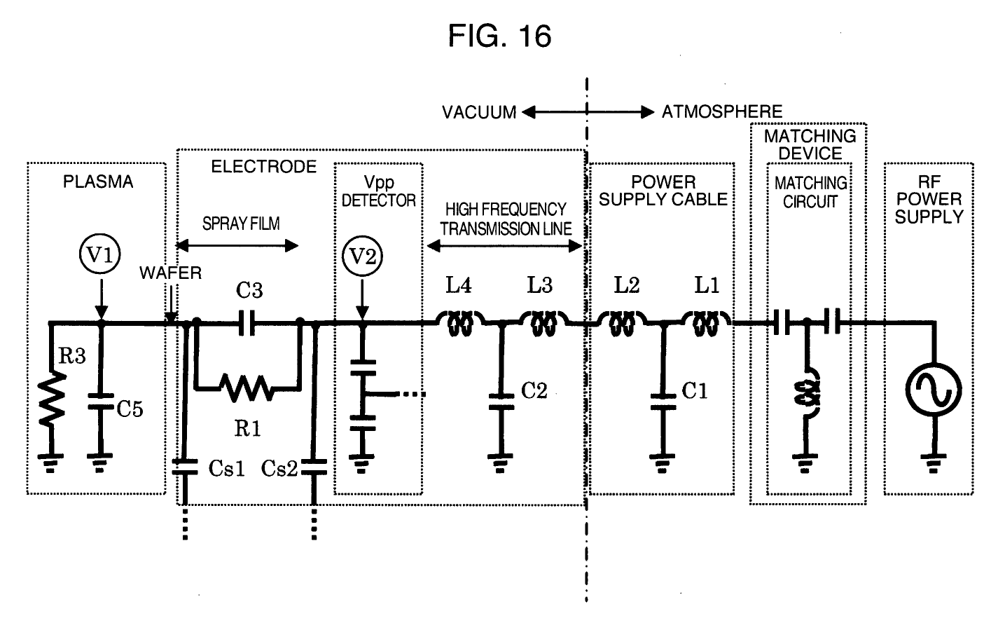

In an extreme case, it can be considered that the detector is built in the electrode as shown in FIG. 16. The arrangement shown in FIG. 16 has no inductance between the detector and the electrode, and thus substantially it can eliminate the effect of the resonance phenomenon itself. This method, however, has some problems, and it is thus unreliable. These problems are as follows. (1) Basically, the electric components (resistors, capacitors, coils, diodes and so on) must be used in the atmosphere, and thus they are not guaranteed for their performance when they are used in vacuum. (2) The electric components are sure to generate heat, and cannot be continuously used in vacuum because most of the generated heat cannot be radiated. Alternatively, a special structure for the heat radiation is necessary, thus increasing the cost of the apparatus. (3) The components might be degraded by a corrosive gas. (4) When a film is deposited over the electric components, it could affect the circuit operation. (5) The high-frequency power for the generation of plasma bends around, and thus it could damage the circuits. (6) Similarly, the high-frequency power for the generation of plasma bends around, and thus causes plasma to be generated around the circuits with the result that it could damage the circuits and affect the circuit operation. These problems could be solved, but in that case, the apparatus might become very expensive and be unreliable. If a small detector could be mounted on the atmosphere-side of the electrode to solve the problems as shown in FIG. 14, the detector should not be purposely provided in vacuum with major demerits. The method shown in FIG. 14 can be said to be very practical from this point of view.

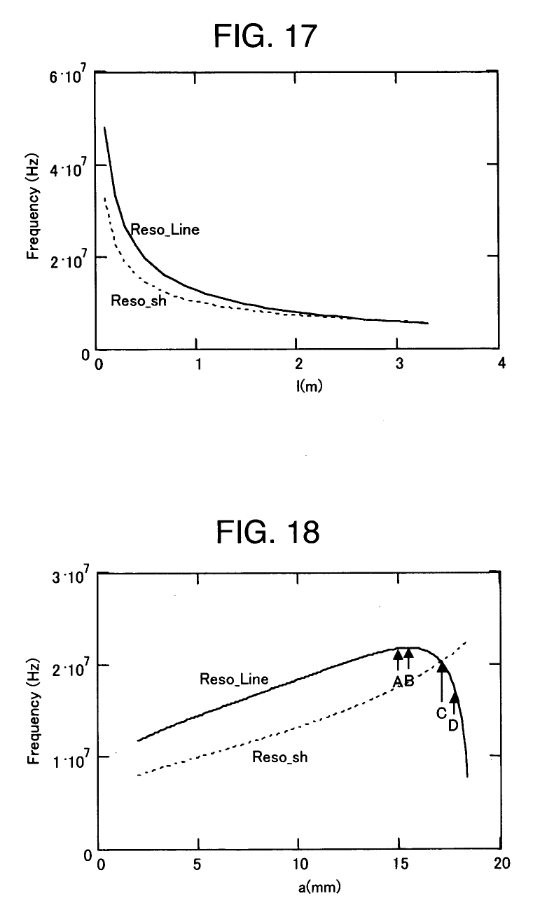

The l-dependence under the conditions of a=11.9 mm, b=18.5 mm and c=22 mm will be examined considering the arrangement shown in FIG. 14. FIG. 17 shows the result. From FIG. 17, it will be understood that the resonant frequency can be greatly raised by decreasing the length l. The resonant frequency (Reso_sh) due to the ion sheath becomes high when the inductance expressed by the equation (7) is reduced. However, the resonant frequency (Reso_Line) due to the high-frequency transmission lines is drastically increased because the electrostatic capacitance expressed by the equation (8) and the inductance expressed by the equation (7) simultaneously decrease. Naturally, according to the equations (7) through (10), the Reso_Line→∞, and Reso_sh→∞ when l→0.

As described above, it will be understood that, if the length l is reduced, the resonant frequency can be drastically raised. Thus, when the length l of the high-frequency transmission line under the electrode is selected to be practically 0.5 m, the a-dependence of the resonant frequency is as shown in FIG. 18. From the comparison of FIG. 18 with the result shown in FIG. 13, it will be seen that the resonant frequency is increased 2˜4 times and that the optimum value of a is different. Here, in the same way as in FIG. 13, the optimum solution for the curve shown in FIG. 18 will be derived. The four points of A, B, C and D written in FIG. 18 will be examined. The point B is at a position of (a=15.51 mm) and corresponds to the maximum value of the Reso_Line. Point A is at a smaller position of radius a than point B, and this position is assumed as a=15.0 mm. Point C is the position corresponding to the intersection (a=17.093 mm) between the curves of Reso_Line and Reso_sh. Point D is at a larger position of radius a than point C, and this position is assumed as a=18.0 mm. The lowest resonant frequencies fL for these four points are calculated as follows.

For point A, fL: fL=min (20.676 MHz, 17.521 MHz)=17.521 MHz,

For point B, fL: fL=min (21.752 MHz, 18.11 MHz)=18.11 MHz,

For point C, fL: fL=min (20.23 MHz, 20.23 MHz)=20.23 MHz, and

For point D, fL: fL=min (15.162 MHz, 21.713 MHz)=15.162 MHz.

Thus, the point C in the figure is the optimum solution, or a=17.093 mm, and fL=20.23 MHz. In addition, Cap=879 pF, and Induct=0.039 μH. Here, it should be noted that the optimum solution in FIG. 18 is the intersection of the curves of Reso_Line and Reso_sh, but the optimum solution in FIG. 13 is another location than the intersection. Here, only the radius a is optimized on the assumption that a certain restriction is placed on b, c and l.

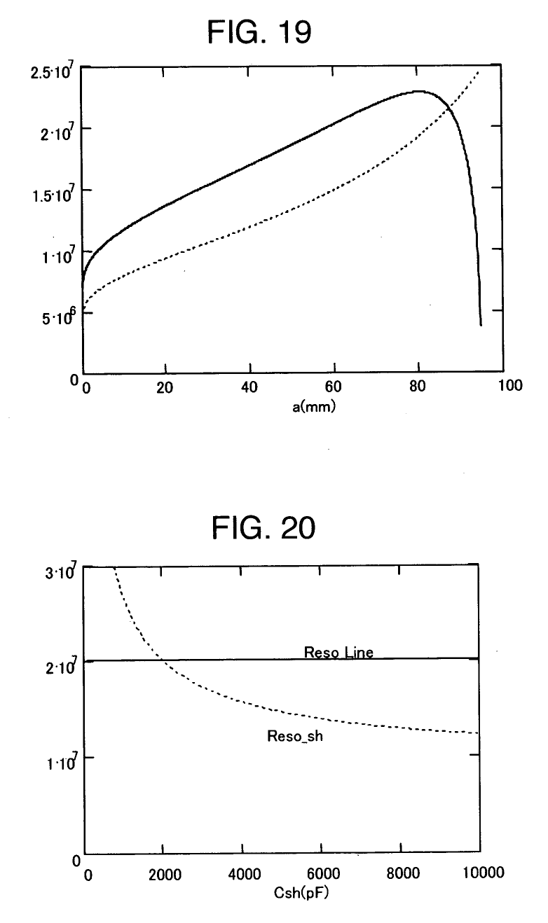

The optimum solution must be essentially estimated from the combination of a, b and c to maximize the equation (11) with respect to a finite value of length l. As might be expected, the factors a, b and c are generally limited not only by the resonant frequency but also by restrictions determined by other conditions such as the structure aspect of enough strength in materials and so on and the electric aspect of withstand voltage or the like. For example, in order for the structure to be strengthened enough, the difference of (c−b) for a material of stainless steel is required to be more than 5 mm, and in order for the withstand voltage to be increased, the difference of (b−a) must be more than 5 mm. The combination of a, b and c must be the optimum a, b and c including the restrictions from other conditions. If the optimization is performed under the conditions of l=0.5 m, 2 mm<a<b<c<100 mm, b−a≧5 mm and C−b≧5 mm, the values of a=80.709 mm, b=95 mm and c=100 mm are obtained as the combination of a, b and c that maximize the Reso_Line of the equation (9). In addition, the values of a=90 mm, b=95 mm and c=100 mm as the combination that maximizes the Reso_sh of the equation (10). The reason for such values of b and c is that (1) the resonant frequency increases with the decrease of the outer conductor thickness as indicated by the result of FIG. 12 and that (2) the inductance decreases with the increase of the absolute values of a, b and c as indicated by the equation (7). The factors b and c certainly always have these behaviors in any case. This optimization is eventually equal to the optimization of factor a. The optimum solution can be obtained as a=87.773 mm, fL=21.512 MHz from the intersection of the curves Reso_Line and Reso_sh as shown in FIG. 19. Thus, the optimization is completed.

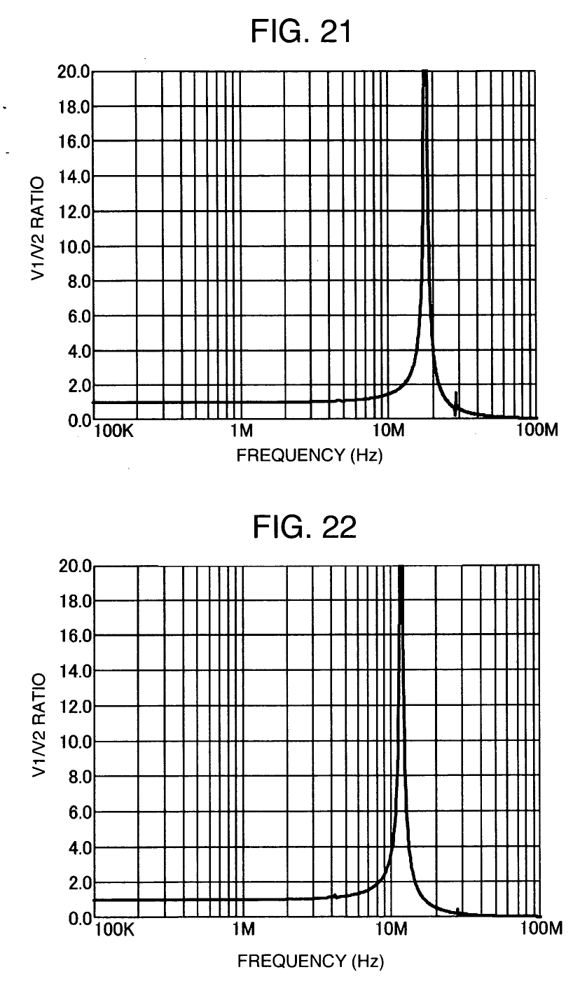

Consequently, the resonant frequency is checked out when the plasma occurrence condition is actually changed. For this purpose, the dependence of the resonant frequency on the electrostatic capacitance Csh of the sheath is examined under the conditions of a=17.1 mm, b=18.5 mm, c=22 mm, l=0.5 m, Cap=879 pF, Induct=0.039 μH, stray capacitance 700 pF of the electrode, and electrostatic capacitance 7500 pF of spray film. FIG. 20 shows the result. Since only Csh changes, only the Reso_sh decreases with the increase of Csh. Even under the condition of Csh=10000 pF, the Reso_sh is about 12 MHz. The results of circuit simulation for this appearance are shown in FIG. 21 (Csh=2000 pF) and FIG. 22 (Csh=10000 pF). From these figures, it will be understood that almost the same resonant frequency as in the analyzed result of FIG. 20 is reproduced. For the case of this result, the maximum frequency to be applied to the electrode may be 5˜6 MHz.

Thus, it will be understood that the high-frequency transmission lines can be optimized by using the coaxial model. Even if the practical high-frequency transmission line to the electrode is not a perfect cylindrical-type coaxial structure, this model can be used. The problematic factors are the parameters so far treated, or the inductance and stray capacitance of the high-frequency transmission lines, the stray capacitance of the electrode and the electrostatic capacitance (if necessary) of the spray film of the electrode. For example, this model is used to calculate the inductance and stray capacitance of the necessary high-frequency transmission line, and the commercially available electromagnetic analyzing soft is used to analyze the inductance and capacitance of the high-frequency transmission line to the actual electrode. By employing this method, it is possible to make optimum design of, for example, even a rectangular coaxial structure.

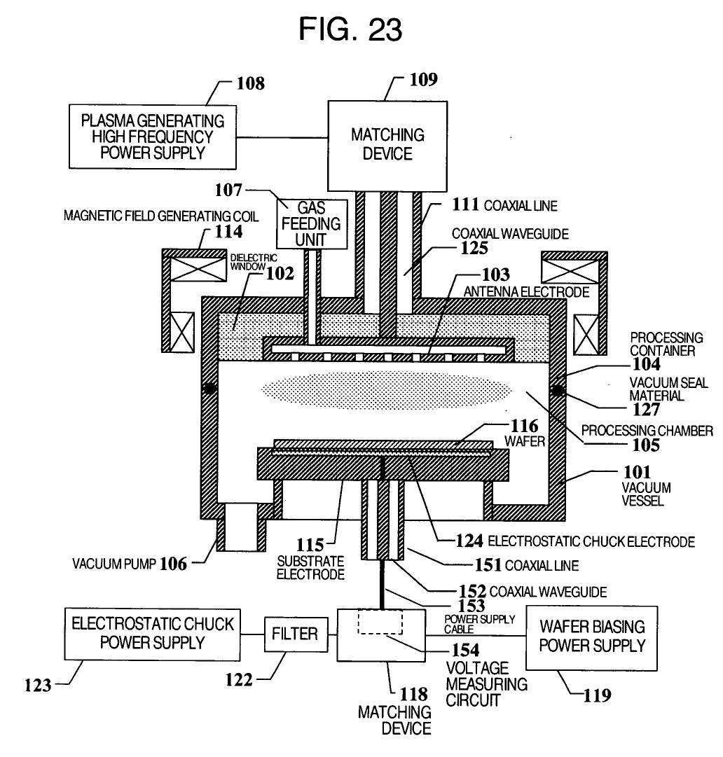

A first example of the above optimum design method will be given below. FIG. 23 is a longitudinal sectional view of an etching chamber used in this invention. This embodiment is an example of the VHF plasma etching apparatus that generates plasma by using VHF (Very High Frequency) and magnetic field. Referring to FIG. 23, on a vacuum vessel 101 is placed a lid for the upper opening that is formed of a cylindrical processing container 104, a flat-shaped antenna electrode 103 made of an electric conductor such as aluminum or nickel, a dielectric window 102 made of electromagnetic wave-transmissible quartz or sapphire. In this case, a vacuum sealing material 127 such as O-ring is applied to the edges of the vessel and the lid to hermetically seal the space between the vessel and the lid, thus a processing chamber 105 being formed in the inside. On the outer periphery of the processing container 104 is provided a field-generating magnetic coil 114 to surround the processing chamber. The antenna electrode 103 is constructed to have a porous structure for allowing etching gas to pass through it. The chlorofluorocarbon such as CF₄, C₄F₆, C₄F₈, C₅F₈, CHF₃ or CH₂F₂, inert gas such as Ar or N₂, and oxide-containing gas such as O₂ or CO are controlled by flow control means (not shown) that is formed of an MFC (mass-flow controller) provided within a gas feed unit 107. Thus, the gasses can be introduced through this gas feed unit 107 into the processing chamber 105. In addition, the vacuum vessel 101 is connected to a vacuum pump 106. The vacuum pump 106 has vacuum pumping means (not shown) formed of TMP (turbo-molecular pump) and has pressure control means (not shown) formed of APC (auto process control). This vacuum pump maintains the processing chamber 105 at a predetermined pressure. In addition, a coaxial line 111 is provided on the top of the antenna electrode 103, and a plasma generating high-frequency power supply (the first high-frequency power supply) 108 (for example, the frequency is 200 MHz) is connected to the antenna electrode 103 through the coaxial line 111, a coaxial waveguide 125 and a matching device 109. Moreover, on the bottom side of the vacuum vessel 101 within the processing chamber is provided a substrate electrode 115 on which a wafer 116 can be placed. This substrate electrode 115 has a coaxial line 151 provided on its underside, as does the antenna electrode 103. This substrate electrode 115 is connected through the coaxial line 151, a coaxial waveguide 152, a power supply cable 153 and a matching device 118 to a wafer biasing power supply (the second high-frequency power supply) 119 (for example, the frequency is 4 MHz). The matching device 118 has a wafer-voltage measuring circuit 154 incorporated. The coaxial line 151 and coaxial waveguide 152 are, for example, the high-frequency transmission line to the electrode shown in FIG. 2, and thus placed in vacuum. The power supply cable 153 is placed in the atmosphere. The substrate electrode 115 also has an electrostatic chuck function for electrostatic absorption of wafer 116. An electrostatic chuck electrode 124 buried in the substrate electrode is connected through a filter 122 to an electrostatic chuck power supply 123. The filter 122 allows the DC power from the electrostatic chuck power supply 123 to pass, but does the power from the high-frequency power supply 108 and wafer biasing power supply 119 to effectively cut off.

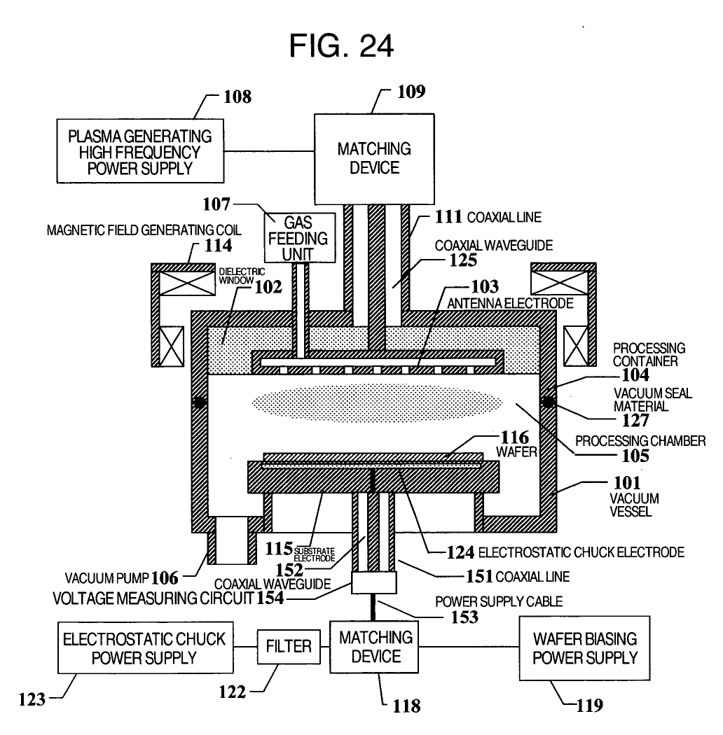

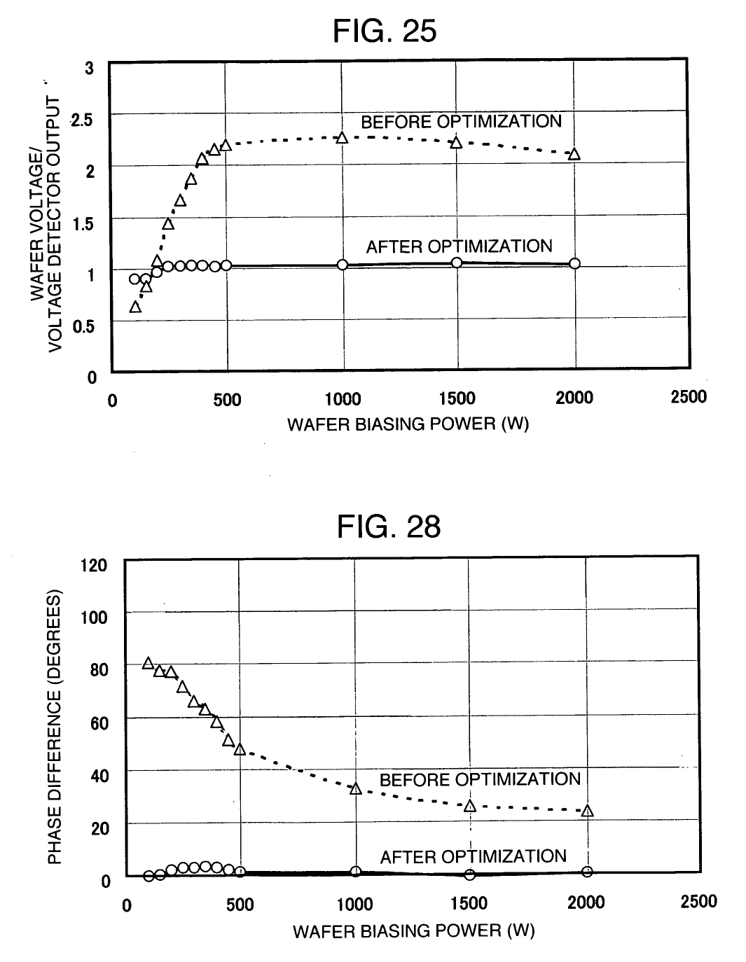

In the apparatus constructed as shown in FIG. 23, the effect of the resonance was observed between the voltage generated on the wafer 116 and the voltage measured by the voltage measuring circuit 154. Thus, the optimizing design method was used to optimize the coaxial line 151 and coaxial waveguide 152. At the same time, the voltage measuring circuit 154 is separated from the matching device 118 and mounted in the atmosphere right under the coaxial line 151 as shown in FIG. 24. FIG. 25 shows the results of the comparison of the directly measured wafer voltage and the output from the voltage detector for each of the non-optimized and optimized constructions of FIGS. 23 and 24. The wafer biasing frequency was 4 MHz. Before the optimization, since the lowest resonant frequency was lower than the wafer biasing frequency, the dependence of the voltage ratio on the wafer-biasing power was greatly changed. After the optimization, the target voltage measurement precision was ±0.05%, that is, the voltage ratio was confined within the range of 1±0.05%. Therefore, the effect of the optimization can be affirmed.

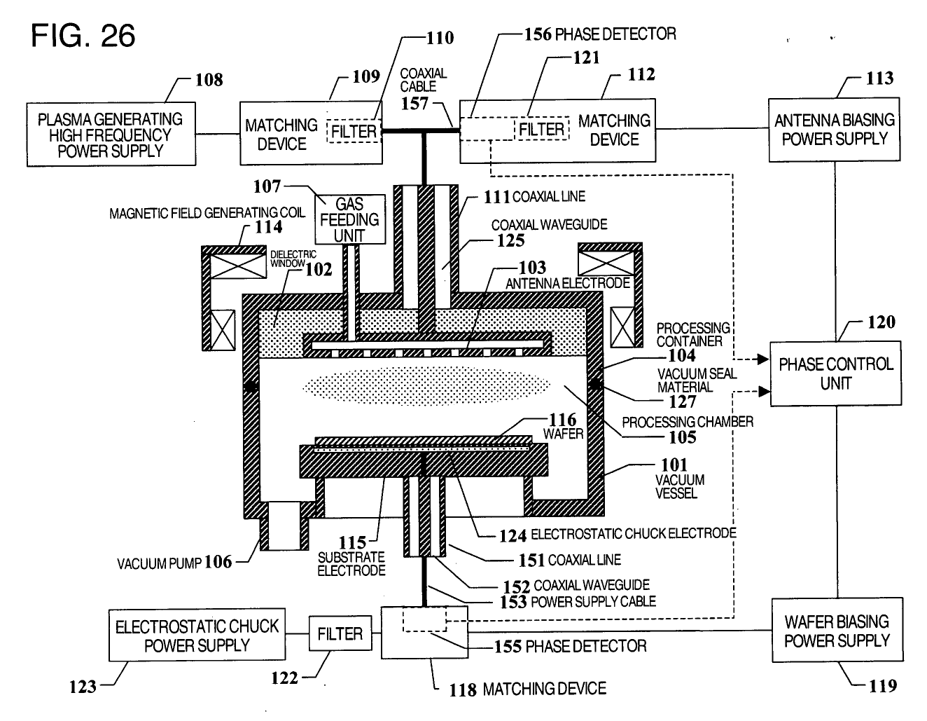

A second example of the above optimization design method will be mentioned below. FIG. 26 is a longitudinal sectional view of an etching chamber used in this invention. This etching chamber is different from the apparatus shown in FIG. 23 in the following points. The antenna electrode 103 is connected to the plasma-generating high-frequency power supply (the first high-frequency power supply) 108 (for example, the frequency is 200 MHz) through the matching device 109 and at the same time it is connected through a matching device 112 to a third high-frequency power supply 113 for biasing the antenna. The antenna-biasing power supply 113 and wafer-biasing power supply 119 are connected to a phase control unit 120 so that the phases of the high-frequency outputs from those power supplies can be controlled. In this case, the frequency of the output from the antenna-biasing power supply 113 was the same (for example, 4 MHz) as that from the wafer-biasing power supply 119. This system of phase control unit controls the phase difference to be kept at a constant value (for example, 180°) between the high frequency from the antenna-biasing power supply that appears at the antenna electrode and the high frequency from the wafer-biasing power supply that appears at the wafer 116. Thus, the biasing power of different phases can be effectively applied to the antenna electrode 103 and wafer 116. Therefore, the detector 156 for detecting the phase at the antenna electrode 103 is incorporated in the antenna biasing matching device 112. The detector 155 for detecting the phase at the wafer 116 is incorporated in the wafer-biasing matching device 118. The phase control unit 120 compares the phases obtained from the two phase detectors 155 and 156 and controls the two high-frequency power supplies 113 and 119 to produce high-frequency outputs with a predetermined phase difference determined according to the result of the comparison. In addition, in order to improve the reliability of the control, the matching device 109 has incorporated therein a filter 110 for cutting off the frequency from the high-frequency power supply 113. Similarly, the matching device 112 has incorporated therein a filter 121 for cutting off the frequency from the high-frequency power supply 108. The outputs from the two matching devices 109 and 112 are summed by using a coaxial cable 157, and fed to the coaxial structure 111 as the high-frequency transmission line to the antenna electrode.

In the structure shown in FIG. 26, the effect of the resonance appeared, and as a result, the output from the wafer-biasing power supply 119 greatly changed the phase difference between the phase of the high frequency generated at the wafer 116 and the phase produced from the wafer-biasing phase detector 155. In addition, the output from the antenna-biasing power supply 113 much changed the phase difference between the phase of the high frequency generated at the antenna electrode 103 and the phase produced from the antenna-biasing phase detector 156. The effect of the resonance on the wafer-biasing phase detector 155 was caused by the ion sheath produced on the wafer 116 and the high-frequency transmission lines 151, 152 and 153 as described above. However, the effect of the resonance on the antenna-biasing phase detector 156 was caused by the ion sheath produced on the antenna electrode 103 and the high-frequency transmission lines 111, 125 and 157. Therefore, these two resonances are independent of each other, and thus required to separately deal with.

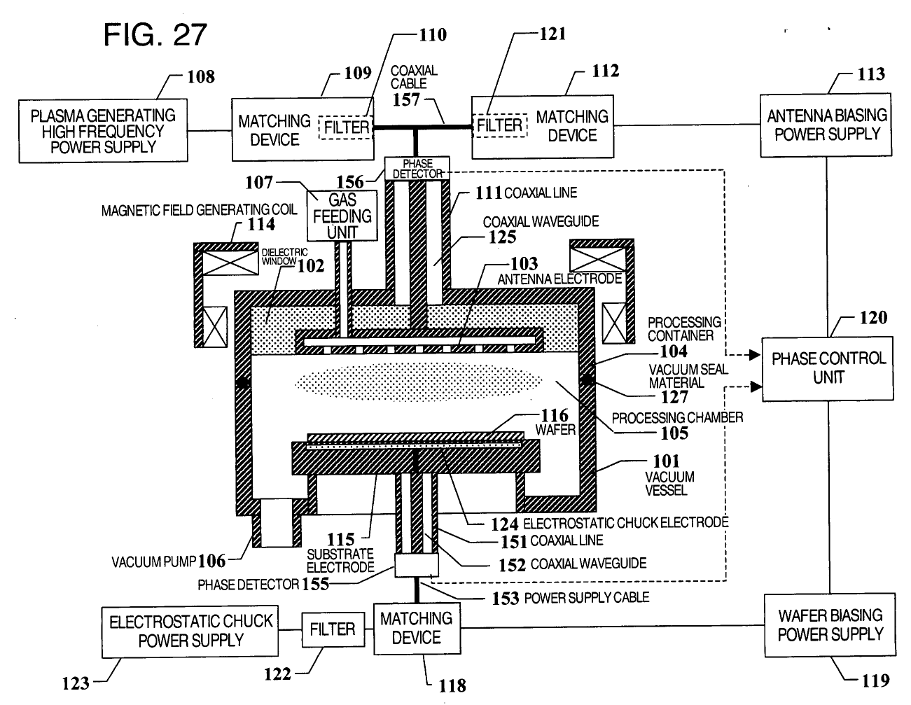

As in the optimization from FIG. 23 to FIG. 24, the above optimization design method was thus used to optimize the coaxial line 151 and coaxial waveguide 152 about the wafer biasing. At the same time, the phase measuring circuit 155 was separated from the matching device 118 and mounted just under the coaxial line 151 to expose to the atmosphere as shown in FIG. 27. In addition, about the antenna electrode, too, the optimization design method was used to optimize the coaxial line 111 and coaxial waveguide 125. At the same time, the phase measuring circuit 156 was separated from the matching device 112 and mounted right under the coaxial line 111 to expose to the atmosphere as shown in FIG. 27. In order to confirm the effect of the optimization, the phase difference between the phase of the high frequency generated at the wafer 116 and the phase produced from the phase measuring circuit 155 was measured for each of the non-optimized structure of FIG. 26 and the optimized structure of FIG. 27. FIG. 28 shows the result. From the result, it will be understood that the phase difference before the optimization increases with the decrease of the wafer-biasing power, but the phase difference after the optimization can be confined within a range of 0±5°. Therefore, the optimization can be confirmed to be effective.

Thus, according to the invention, the high-frequency transmission circuits and the voltage-and phase-detecting circuits can be optimized in order to increase the resonant frequency due to the ion sheath and the high-frequency transmission lines. Therefore, the high-frequency voltages and phases can be accurately detected. In addition, the plasma processing apparatus can be stably operated to keep the optimum condition.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a vacuum vessel;
a lower electrode provided within said vacuum vessel and on which a sample is placed;
an upper electrode provided to oppose said lower electrode;
a first matching device connected to said lower electrode;
a first power supply for supplying electric power to said lower electrode through said first matching device;
a second matching device connected to said upper electrode;
a second power supply for supplying electric power to said upper electrode through said second matching device;
a first detector provided within or near said first matching device to detect a voltage or phase; and
a second detector provided within or near said second matching device to detect a voltage or phase, wherein
a transmission line provided between said first detector and said lower electrode or a transmission line provided between said second detector and said upper electrode is constructed to meet the following condition,
LC<(4πfB)⁻²
where L is a typical value of inductance that causes a resonance, such as the inductance of said transmission line, C is a typical value of electrostatic capacitance that causes a resonance, such as the stray capacitance of said transmission line or the stray capacitance of plasma ion sheath, and fB is the biasing high frequency to be applied to said upper electrode or said lower electrode.

2. A plasma processing apparatus according to claim 1, wherein said transmission line is a coaxial line that is formed of an inner conductor line and an outer conductor line surrounding said inner conductor line, and said inner and outer conductor lines are made of a nonmagnetic and electrically conductive material.

3. A plasma processing apparatus according to claim 2, wherein the space between said inner and outer conductor lines is kept at a low specific dielectric constant.

4. A plasma processing apparatus according to claim 3, wherein the space between said inner and outer conductor lines is vacuum or filled with gas.

5. A plasma processing apparatus according to claim 2, wherein the outer surface of said inner conductor line and the inner surface of said outer conductor line are coated with Teflon.

6. A plasma processing apparatus comprising:
a vacuum vessel;
a lower electrode provided within said vacuum vessel and on which a sample is placed;
an upper electrode provided to oppose said lower electrode;
a first matching device connected to said lower electrode;
a first power supply for supplying electric power to said lower electrode through said first matching device;
a second matching device connected to said upper electrode;
a second power supply for supplying electric power to said upper electrode through said second matching device;
a first detector provided within or near said first matching device to detect voltage or phase; and
a second detector provided within or near said second matching device to detect voltage or phase, wherein
a transmission line provided between said first detector and said lower electrode or a transmission line provided between said second detector and said upper electrode is a coaxial line formed of an inner conductor line and an outer conductor line surrounding said inner conductor line, and
the radius a of said inner conductor line of said transmission line, the inner diameter b of said outer conductor line and the outer diameter c of said outer conductor line are determined so that the lowest resonant frequency fL expressed by the following equation can take the maximum value,
$$fL = min ( Reso\_Line , Reso\_sh )$$
$$where$$
$$Reso\_Line = \frac{1}{2 π \sqrt{( Cap + Cs ) \times Induct}} , \\ Reso\_sh = \frac{1}{2 π \sqrt{Ctot \times Induct}} ,$$
Cs is the stray capacitance of said upper electrode or said lower electrode,
Cap is the electrostatic capacitance between said inner and outer conductor lines and given by the following equation,
$$Cap = \frac{2 πɛ l}{ln ( \frac{a}{b} )} ,$$
l is the length of said transmission line,
Induct is the inductance of said transmission line, and given by the following equation,
$$Induct = \frac{l}{4 π} [ \frac{μ 1}{2} + 2 μ 0 ln ( \frac{b}{a} ) + \frac{μ 2}{{c}^{2} - {b}^{2}} ( \frac{2 {c}^{4}}{{c}^{2} - {b}^{2}} ln ( \frac{c}{b} ) - \frac{3 {c}^{2} - {b}^{2}}{2} ) ] ,$$
μ1 is the relative permeability of said inner conductor line,
μ2 is the relative permeability of said outer conductor line, and
Ctot is the resultant of the electrostatic capacitance
Cel of said upper or lower electrode and the electrostatic capacitance Csh of ion sheath, and given by the following equation,
$$Ctot = \frac{Csh \times Cel}{Csh \times Cel}$$

7. A plasma processing apparatus according to claim 6, wherein said inner conductor line and said outer conductor line are made of a nonmagnetic and electrically conductive material.

8. A plasma processing apparatus comprising:
a vacuum vessel;
a lower electrode provided within said vacuum vessel and on which a sample is placed;
an upper electrode provided to oppose said lower electrode;
a first matching device connected to said lower electrode;
a first power supply for supplying electric power to said lower electrode through said first matching device;
a second matching device connected to said upper electrode;
a second power supply for supplying electric power to said upper electrode through said second matching device;
a first detector provided within or near said first matching device to detect voltage or phase;
a second detector provided within or near said second matching device to detect voltage or phase;
a coaxial line that transmits electric power from said first matching device to said lower electrode and that is extended from within said vacuum vessel down to the atmosphere of the outside of said vacuum vessel; and
a voltage-or phase-detecting detector provided separately from said first matching device and connected to the atmosphere side of said coaxial line.

9. A plasma processing apparatus according to claim 8, wherein said coaxial line is formed of an inner conductor line and an outer conductor line surrounding said inner conductor line, and said inner conductor line and said outer conductor line are made of a nonmagnetic and electrically conductive material.

10. A plasma processing apparatus comprising:
a vacuum vessel;
a lower electrode provided within said vacuum vessel and on which a sample is placed;
an upper electrode provided to oppose said lower electrode;
a first matching device connected to said lower electrode;
a first power supply for supplying electric power to said lower electrode through said first matching device;
a second matching device connected to said upper electrode;
a second power supply for supplying electric power to said upper electrode through said second matching device;
a first detector provided within or near said first matching device to detect voltage or phase;
a second detector provided within or near said second matching device to detect voltage or phase;
a coaxial line that transmits electric power from said second matching device to said upper electrode and that is extended from within said vacuum vessel up to the atmosphere of the outside of said vacuum vessel; and
a voltage-or phase-detecting detector provided separately from said second matching device and connected to the atmosphere side of said coaxial line.

11. A plasma processing apparatus according to claim 10, wherein said coaxial line is formed of an inner conductor line and an outer conductor line surrounding said inner conductor line, and said inner conductor line and said outer conductor line are made of a nonmagnetic and electric conductive material.
